(19) United States
(12) Patent Application Publication
(10) Pub. No.: US 2012/0178230 A1
(43) Pub. Date: Jul. 12, 2012

(54) METHOD FOR FABRICATING TRENCH DMOS TRANSISTOR

(75) Inventor: Le Wang, Wuxi (CN)

(73) Assignees: CSMC TECHNOLOGIES FAB2 CO., LTD., Jiangsu (CN); CSMC TECHNOLOGIES FAB1 CO., LTD., Jiangsu (CN)

(21) Appl. No.: 13/394,679

(22) PCT Filed: Sep. 26, 2010
(86) PCT No.: PCT/CN2010/077318

§ 371 Date: Mar. 7, 2012

(30) Foreign Application Priority Data
Sep. 27, 2009 (CN) 200910175076.7

(51) Int. Cl. H01L 21/336

(52) U.S. Cl. 438/270; 257/E21.419

(57) ABSTRACT

A method for fabricating trench DMOS transistor includes: forming an oxide layer and a barrier layer with photolithography layout sequentially on a semiconductor substrate; etching the oxide layer and the semiconductor substrate with the barrier layer as a mask to form a trench; forming a gate oxide layer on the inner wall of the trench; forming a polysilicon layer on the barrier layer, filling up the trench; etching back the polysilicon layer with the barrier layer mask to remove the polysilicon layer on the barrier layer to form a trench gate; removing the barrier layer and the oxide layer; implanting ions into the semiconductor substrate on both sides of the trench gate to form a diffusion layer; coating a photoresist layer on the diffusion layer and defining a source/drain layout thereon; implanting ions into the diffusion layer based on the source/drain layout with the photoresist layer mask to form the source/drain; forming sidewalls on both the sides of the trench gate after removing the photoresist layer; and forming a metal silicide layer on the diffusion layer and the trench gate. Effective result of the present invention is achieved with lower cost and improved efficiency of fabrication.

### FIELD OF THE INVENTION

The present invention relates to the field of manufacturing a semiconductor component, and in particular to a method for fabricating trench DMOS transistor.

### BACKGROUND OF THE INVENTION

A DMOS (Double diffused MOS) transistor is a type of MOSFET (Metal-Oxide-Semiconductor Field-Effect Transistor) in which a transistor area is formed through diffusion. The DMOS transistor typically acts as a power transistor to provide a high-voltage circuit for a power integrated circuit application. The DMOS transistor provides larger current per unit area when a low forward voltage drop is required.

A specific type of DMOS transistor is a trench DMOS transistor in which a channel appears on the inner wall of a trench extending from the source to the drain and the gate is formed in the trench. The trench DMOS has been widely applied in an analogy circuit and a driver, particularly in a high-voltage power part due to its characteristic of high-voltage and large-current driving (the device is structured to enable the drain end to undergo high voltage and integrated highly to achieve a ultra-large W/L (the ratio of width to length of the device channel) in a small area).

As disclosed in a typical method for forming DMOS transistor, e.g., Chinese Patent Application No 96108636 and referring to FIG. 1, an overlying layer 12 is formed of low-concentration n⁻-type semiconductor substance on a high-concentration n⁺-type silicon substrate 10 to thereby form a semiconductor substrate. That is, impurity ions of the same conductivity type are diffused into the high-concentration substrate 10 and the low-concentration overlying layer 12, both of which the semiconductor substrate is constituted. Impurity ions of a conductivity type different from that of the silicon substrate 10 are implanted into the overlying layer 12 of the semiconductor substrate to form a P-type diffusion layer 14 required for a body layer of the trench DMOS transistor to be manufactured in a subsequent process.

As illustrated in FIG. 2, a silicon oxide film (not shown), which is a dielectric film in a defined layout, is formed on the diffusion layer 14, and an ion implantation process is performed using the layout of the silicon oxide film as a mask required for formation of the source so as to form a high-concentration source impurity implanted layer 16.

Then as illustrated in FIG. 3, the lattice of the silicon oxide is removed, and then a silicon oxide film (not illustrated) in a defined layout is formed on the diffusion film 14 to thereby create two symmetric trench areas. Two trenches 15a and 15b with vertical sidewalls are defined by means of reactive ion beam etching or another kind of etching. The two trenches 15a and 15b are as deep as the semiconductor substrate etched until the part of underlying layer 12, and the impurity implanted layer 16 formed between the two trenches 15a and 15b are connected directly with the source. A gate oxide film 18 is formed respectively on the surfaces of the sidewalls and bottoms of the two trenches 15a and 15b in an oxidation process.

As illustrated in FIG. 4, the trenches 15a and 15b are filled with polysilicon while polysilicon is formed on the gate oxide film 18 to thereby form a gate polysilicon film 20. The polysilicon films 20a and 20b formed in the respective trenches 15a and 15b are connected with the gate in a subsequent metal wiring process, the source impurity implanted layer 16 is connected with the source, and the semiconductor substrate is connected with the collector.

The existing procedure of forming a DMOS transistor, in which a photolithography or etching process has to be performed approximately five times, is complicated, high cost, low efficiency and time-consuming in fabrication. Moreover, the device may be overlaid with a significant error without a self-aligned process.

### SUMMARY OF THE INVENTION

One object of the present invention is to provide a method for fabricating trench DMOS transistor efficiently at a low cost.

To address the issue, the invention provides a method for fabricating trench DMOS transistor, which includes: forming an oxide layer and a barrier layer with photolithography layout sequentially on a semiconductor substrate; etching the oxide layer and the semiconductor substrate with the barrier layer as a mask to define a trench; forming a gate oxide layer inside the trench; forming a polysilicon layer on the barrier layer, filling up the trench with the polysilicon layer; etching back the polysilicon layer with the barrier layer mask to remove the polysilicon layer so as to form a trench gate; removing the barrier layer and the oxide layer; implanting ions into the semiconductor substrate on both sides of the trench gate to form a diffusion layer; coating a photoresist layer on the diffusion layer and defining a source/drain layout thereon; implanting ions into the diffusion layer based on the source/drain layout with the photoresist layer mask to form the source/drain; forming sidewalls on both the sides of the trench gate after removing the photoresist layer; and forming a metal silicide layer on the diffusion layer and the trench gate.

In an embodiment, the semiconductor substrate includes an N-type silicon substrate and an N-type epitaxial layer arranged thereon. The trench is located in the N-type epitaxial layer.

Optionally, the oxide layer is formed by means of thermal oxidation or chemical vapor deposition or physical vapor deposition. The oxide layer is of silicon dioxide with a thickness of 250 Å to 350 Å.

Optionally, the barrier layer is formed by means of chemical vapor deposition or physical vapor deposition. The barrier layer is of silicon nitride with a thickness of 2500 Å to 3500 Å.

Optionally, the gate oxide layer is formed by means of thermal oxidation or rapid annealing oxidation. The gate oxide layer is of silicon dioxide or nitrogen-containing silicon dioxide with a thickness of 300 Å to 1000 Å.

Optionally, during the formation of the diffusion layer, P-type ions are implanted into the semiconductor substrate. The P-type ions are boron ions implanted at a dosage of 1E13/cm² to 3E13/cm² with energy of 70KeV to 100KeV.

Optionally, during the formation of the source/drain, N-type ions are implanted into the diffusion layer. The N-type ions are arsenic ions implanted at a dosage of 1E16/cm² to 5E16/cm² with energy of 70KeV to 130KeV.

The invention offers the following advantages over the prior art: the fabricating steps of the transistor can be reduced because the photolithography process is carried out only twice, thus resulting in a lowered cost and improved fabricating efficiency.

### BRIEF DESCRIPTION OF THE DRAWINGS

FIG. 1 to FIG. 4 illustrate schematic diagrams of the existing procedure of fabricating a DMOS transistor;

FIG. 5 illustrates a flow chart of an embodiment of a method for fabricating a DMOS transistor according to the invention; and

FIG. 6 to FIG. 14 are schematic diagrams of a method for fabricating a DMOS transistor according to the invention.

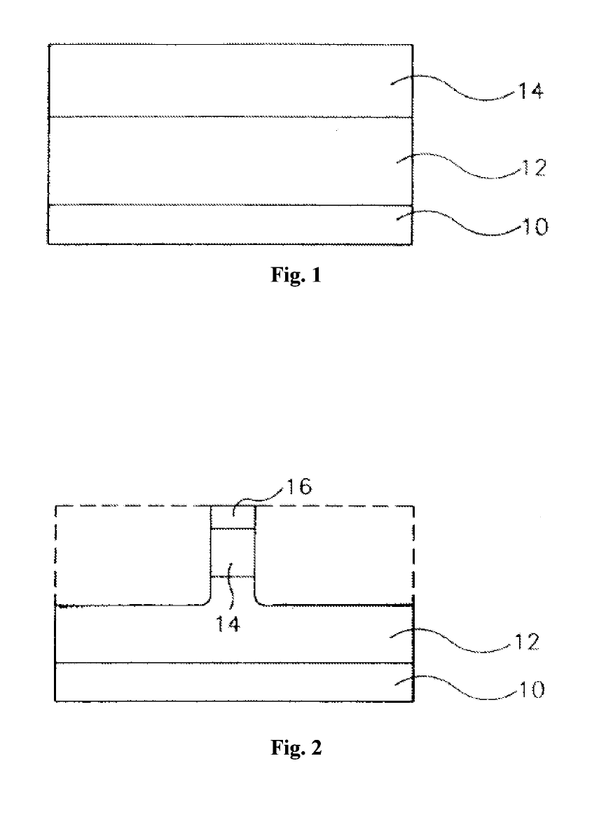

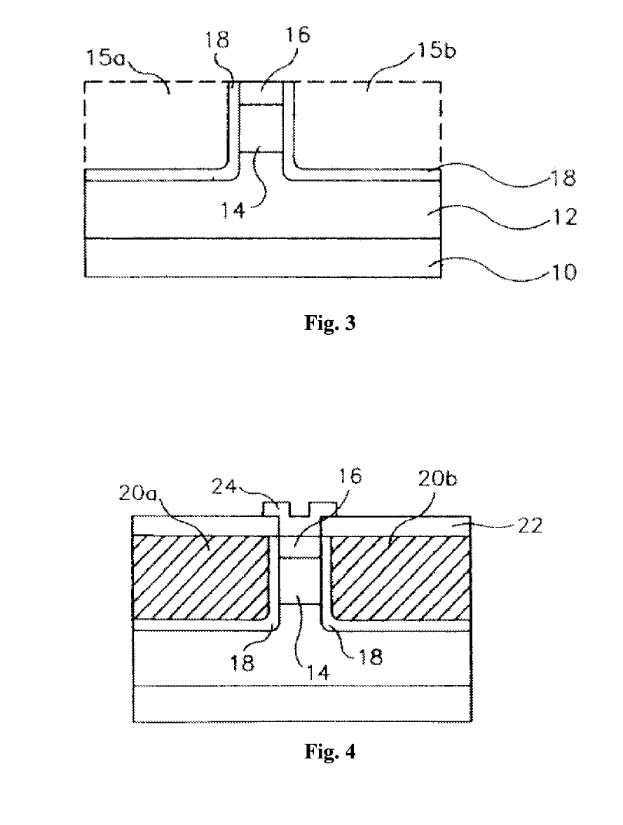

### DETAILED DESCRIPTION OF THE EMBODIMENTS

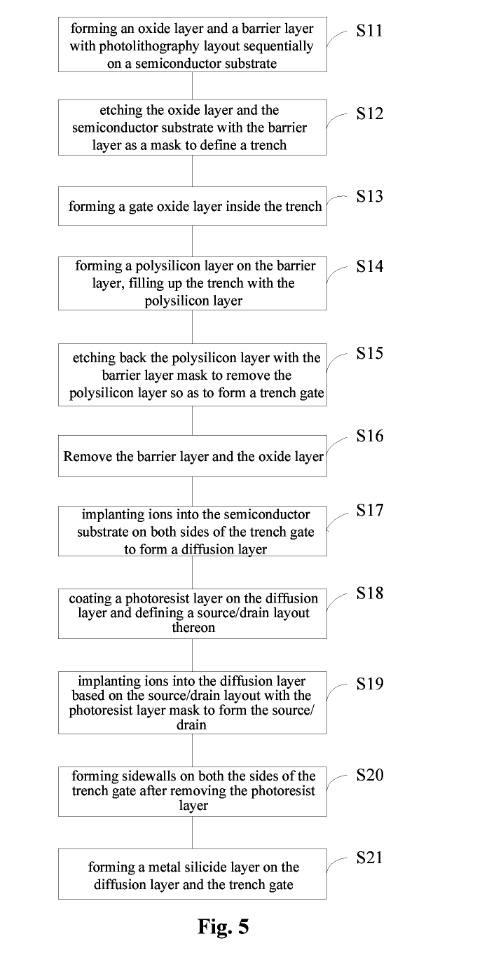

FIG. 5 illustrates a flow chart of an embodiment of a method for fabricating DMOS transistor according to the invention in which the step S11 is performed to form an oxide layer and a barrier layer with photolithography layout sequentially on a semiconductor substrate; the step S12 is performed to etch the oxide layer and the semiconductor substrate using the barrier layer as a mask to form a trench; the step S13 is performed to form a gate oxide layer on the inner wall of the trench; the step S14 is performed to form a polysilicon layer on the barrier layer to fill up the trench with the polysilicon layer; the step S15 is performed to etch back the polysilicon layer using the barrier layer as a mask to remove the polysilicon layer on the barrier layer and form a trench gate; the step S16 is performed to remove the barrier layer and the oxide layer; the step S17 is performed to implant ions into the semiconductor substrate on both sides of the trench gate to form a diffusion layer; the step S18 is performed to form a photoresist layer on the diffusion layer and define a source/drain pattern; the step S19 is performed to implant ions into the diffusion layer in the source/drain pattern using the photoresist layer as a mask to form the source/drain; the step S20 is performed to form sidewalls on both the sides of the trench gate after removing the photoresist layer; and the step S21 is performed to form a metal silicide layer on the diffusion layer and the trench gate.

The number of process steps of fabricating the device can be reduced because the photolithography process is performed only twice according to the invention, thus resulting in a lowered cost and improved efficiency of fabrication.

An embodiment of the invention will be detailed below with reference to the drawings.

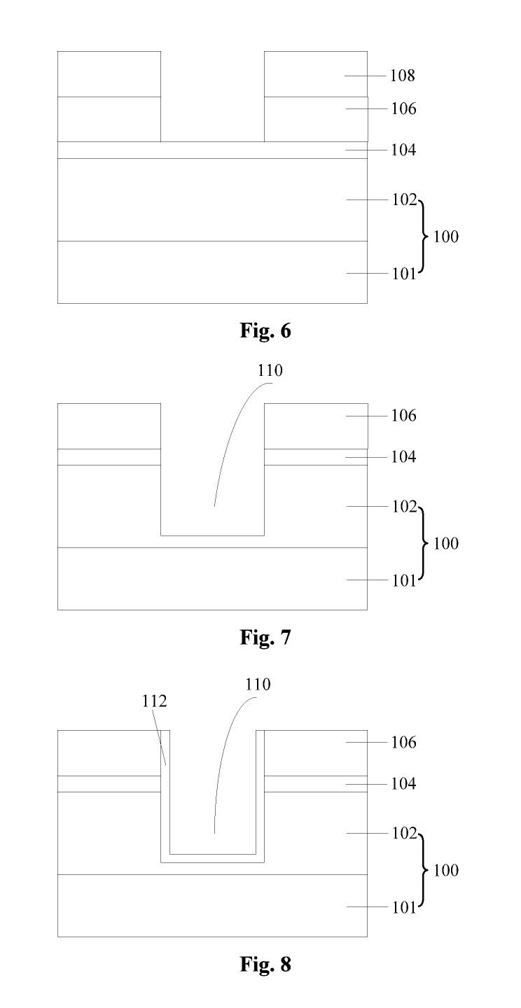

FIG. 6 to FIG. 14 illustrate schematic diagrams of a method for fabricating a DMOS transistor according to the invention. As illustrated in FIG. 6, a high-concentration n⁺-type silicon substrate 101 is prepared; and an epitaxial layer 102 of the same conductivity type as that of the silicon substrate 101 is formed on the high-concentration n⁺-type silicon substrate 101, where low-concentration n⁻-type ions are doped in the epitaxial layer 102. Impurity ions of the same conductivity type are diffused into the n⁺-type silicon substrate 101 and the n⁻-type epitaxial layer 102 to constitute a semiconductor substrate 100.

Further referring to FIG. 6, an oxide layer 104 of silicon dioxide with a thickness of 250 Å to 350 Å is formed on the n⁻-type epitaxial layer 102 by thermal oxidation method or chemical vapor deposition method or physical vapor deposition method; and a barrier layer 106 of silicon nitride with a thickness of 2500 Å to 3500 Å is formed on the oxide layer 104 by chemical vapor deposition method or physical vapor deposition method to protect an underlying film layer from being damaged in a subsequent etching process. A first photoresist layer 108 is formed on the barrier layer 106 by spin-coating method and subject to exposure and development process to define a trench photolithography layout thereon. Next the barrier layer 106 is etched in the trench layout using the first photoresist layer 108 as a mask until the oxide layer 104 is exposed to form a trench opening, where the barrier layer 106 is etched by dry etching method using gases of C₄F₈ and CO with a flow ratio of 1:15.

As illustrated in FIG. 7, the first photoresist layer is removed by ashing method or wet etching method; and the oxide layer 104 and the n⁻-type epitaxial layer 102 are etched in the trench opening using the barrier 106 as a mask to form a trench 110, where the oxide layer 104 and the n⁻-type epitaxial layer 102 are etched by dry etching method using gases of Cl₂, HBr and CF₄ with a flow ratio of 1:10:1.5.

Referring to FIG. 8, a gate oxide layer 112 of silicon dioxide or nitrogen-containing silicon dioxide with a thickness of 300 Å to 1000 Å is grown on the inner wall of the trench 100 by thermal oxidation method or rapid annealing oxidation method.

As illustrated in FIG. 9, the trench is filled up with a polysilicon layer to form a trench gate 114. Specifically, firstly the polysilicon layer is formed on the barrier layer 106 by chemical vapor deposition method to fill up the trench with the polysilicon layer; and then the polysilicon layer is etched using the barrier layer 106 as a mask in a back-etching process until the barrier layer 106 is exposed to leave the polysilicon layer only in the trench.

In the present embodiment, the back-etching process is dry etching using a gas of Cl₂.

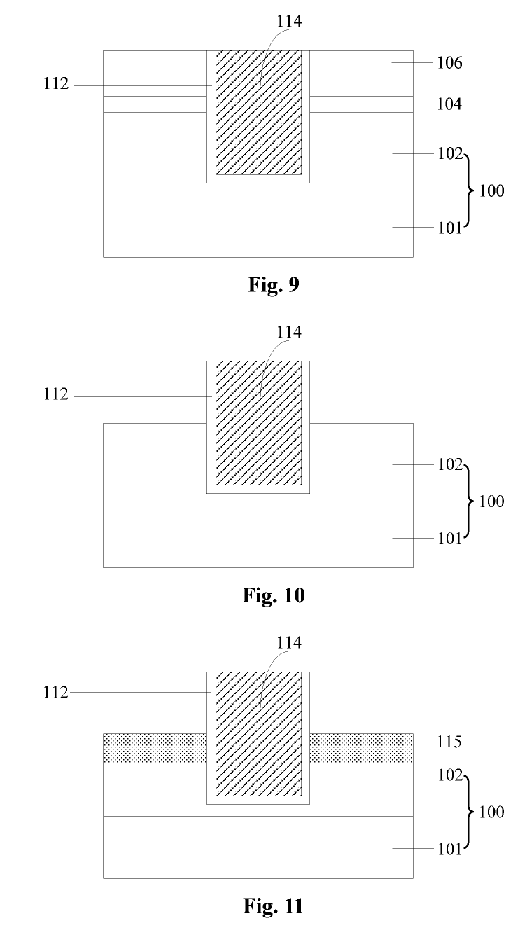

Referring to FIG. 10, the barrier layer 106 and the oxide layer 104 are removed to expose a part of the trench gate 114, that is, the surface of the trench gate 114 is higher than the surface of the n⁻-type epitaxial layer 102, where the barrier layer 106 and the oxide layer 104 are removed by wet etching method.

As illustrated in FIG. 11, P-type ions are implanted into the n⁻-type epitaxial layer 102 using the trench gate 114 as a mask to form a diffusion layer 115. The diffusion layer 115 is used to form a channel area.

In the present embodiment, the P-type ions can be boron ions or boron fluoride ions, and if boron ions are implanted during the formation of diffusion layer 115, a dosage of boron ions ranges from 1E13/cm² to 3E13/cm² and energy of boron ions ranges from 70KeV to 100KeV to form the diffusion layer 115 with a thickness of 1 μm to 2 μm.

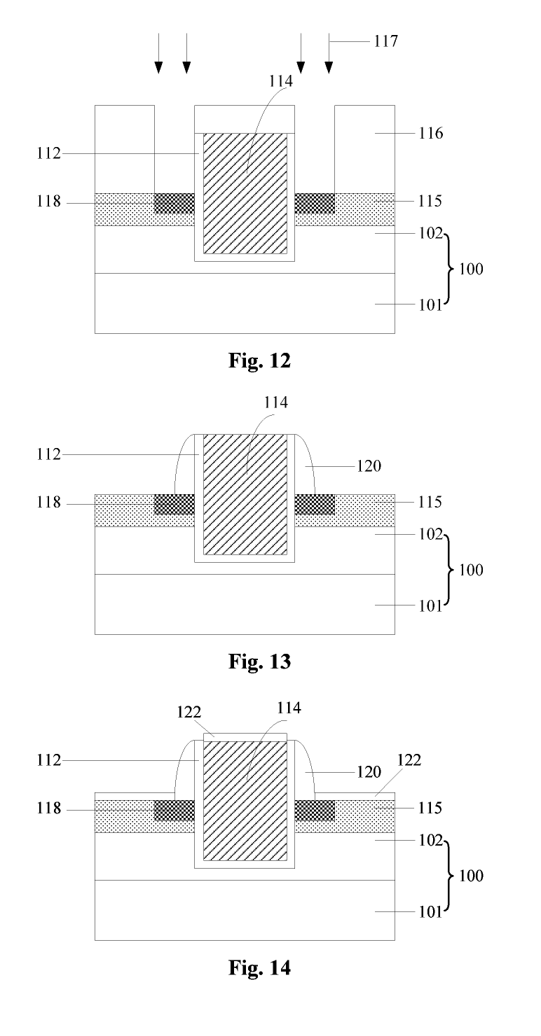

Referring to FIG. 12, a second photoresist layer 116 is formed on the diffusion layer 115 by spin-coating method and subject to exposure and development processes to define a source/drain layout thereon; and next N-type ions 117 are implanted into the diffusion layer 115 on both sides of the trench gate 114 based on the source/drain layout using the second photoresist layer 116 as a mask to form a source/drain 118.

In the present embodiment, the N-type ions can be arsenic ions or phosphor ions, and if arsenic ions are implanted in the formation of the source/drain 118, a dosage of arsenic ions ranges from 1E16/cm² to 5E16/cm² and energy of arsenic ions ranges from 70KeV to 130KeV to form the source/drain 118 with a thickness of 0.3 μm.

Next an annealing process is performed to diffuse the ions uniformly.

As illustrated in FIG. 13, the second photoresist layer is removed by ashing method or wet etching method.

Further referring to FIG. 13, sidewalls 120 are formed on both sides of the part of the trench gate 114 higher than the surface of the diffusion layer 115. Specifically, an oxide layer is formed on the diffusion layer 115 and around the part of the trench gate 114 higher than the surface of the diffusion layer 115 by low-pressure chemical vapor deposition method wherein the oxide layer is constituted of silicide dioxide, a combination of silicon oxide and silicon nitride or silicon oxide-silicon nitride-silicon oxide (ONO); and the oxide layer is etched by reactive ion anisotropic etching method.

As illustrated in FIG. 14, a metal silicide layer of titanium silicide with a thickness of 80 Å to 350 Å is formed on the diffusion layer 115 and the trench gate 114. Specifically, a metal layer of titanium is formed on the diffusion layer 115, the sidewalls 120 and the trench gate 114 by chemical vapor deposition method and then is subject to thermal treatment to be bonded with silicon in the diffusion layer 115, the sidewalls 120 and the trench gate 114 to form the metal silicide layer, i.e., the titanium silicide layer; and the metal silicide layer on the sidewalls 120 is removed by wet etching method to break automatically a connection between the gate and the source/drain to thereby create an ohmic contact process.

Although the invention has been disclosed above in the preferred embodiments thereof, the invention will not be limited thereto. Those skilled in the art can make various variations and modifications without departing from the spirit and scope of the invention, and therefore the scope of the invention shall be defined as in the appended claims.

1. A method for fabricating trench DMOS transistor, comprising:
forming an oxide layer and a barrier layer with photolithography layout sequentially on a semiconductor substrate;
etching the oxide layer and the semiconductor substrate with the barrier layer as a mask to define a trench;
forming a gate oxide layer on the inner wall of the trench;
filling up the trench with polysilicon so as to form a trench gate;
removing the barrier layer and the oxide layer;
implanting ions into the semiconductor substrate on both sides of the trench gate to form a diffusion layer;
coating a photoresist layer on the diffusion layer and defining a source/drain layout thereon;
implanting ions into the diffusion layer based on the source/drain layout with the photoresist layer mask to form the source/drain;
forming sidewalls on both the sides of the trench gate after removing the photoresist layer; and
forming a metal silicide layer on the diffusion layer and the trench gate.

2. The method for fabricating trench DMOS transistor according to claim 1, wherein the semiconductor substrate comprises an N-type silicon substrate and an N-type epitaxial layer arranged thereon, and wherein in forming the trench gate, first form a polysilicon layer on the barrier layer, and etch back the polysilicon layer with the barrier layer mask to remove the polysilicon layer on the barrier layer.

3. The method for fabricating trench DMOS transistor according to claim 2, wherein the trench is located in the N-type epitaxial layer.

4. The method for fabricating trench DMOS transistor according to claim 1, wherein the oxide layer is formed by means of thermal oxidation or chemical vapor deposition or physical vapor deposition.

5. The method for fabricating trench DMOS transistor according to claim 4, wherein the oxide layer is of silicon dioxide with a thickness of 250 Å to 350 Å.

6. The method for fabricating trench DMOS transistor according to claim 1, wherein the barrier layer is formed by means of chemical vapor deposition or physical vapor deposition.

7. The method for fabricating trench DMOS transistor according to claim 6, wherein the barrier layer is of silicon nitride with a thickness of 2500 Å to 3500 Å.

8. The method for fabricating trench DMOS transistor according to claim 1, wherein the gate oxide layer is formed by means of thermal oxidation or rapid annealing oxidation.

9. The method for fabricating trench DMOS transistor according to claim 8, wherein the gate oxide layer is of silicon dioxide or nitrogen-containing silicon dioxide with a thickness of 300 Å to 1000 Å.

10. The method for fabricating trench DMOS transistor according to claim 1, wherein during the formation of the diffusion layer, P-type ions are implanted into the semiconductor substrate.

11. The method for fabricating trench DMOS transistor according to claim 10, wherein the P-type ions are boron ions implanted at a dosage of 1E13/cm² to 3E13/cm² with energy of 70KeV to 100KeV.

12. The method for fabricating trench DMOS transistor according to claim 1, wherein during the formation of the source/drain, N-type ions are implanted into the diffusion layer.

13. The method for fabricating trench DMOS transistor according to claim 12, wherein the N-type ions are arsenic ions implanted at a dosage of 1E16/cm² to 5E16/cm² with energy of 70KeV to 130KeV.
